(19) United States
(12) Patent Application Publication
(10) Pub. No.: US 2004/0160179 A1
(43) Pub. Date: Aug. 19, 2004

(54) Electroluminescent display device and manufacturing method thereof

(75) Inventor: Tetsuji Omura, Ogaki-shi (JP)

Correspondence Address: MORRISON & FOERSTER LLP, 1650 TYSONS BOULEVARD, SUITE 300, MCLEAN, VA, 22102, US

(73) Assignee: Sanyo Electric Co., Ltd., Moriguchi-city (JP)

(21) Appl. No.: 10/727,983

(22) Filed: Dec. 5, 2003

(30) Foreign Application Priority Data
Dec. 6, 2002 (JP) 2002-354505

(51) Int. Cl. H05B 33/04; H05B 33/10

(52) U.S. Cl. 313/512; 428/68; 428/156; 428/690; 428/917; 257/100

(57) ABSTRACT

The invention is directed to improving of reliability in resistance to temperature changes by preventing a desiccant layer from peeling off or tearing in an organic EL panel. A pocket portion is formed by etching a sealing glass substrate with hydrofluoric acid by using a plurality of resist patterns disposed in a matrix as a mask. Then, concaves and convexes are formed on a bottom of the pocket portion, i.e. on a surface of the sealing glass substrate. A desiccant layer is formed on the bottom of the pocket portion. By rough-surfacing as above, the anchor effect is generated to increase adhesive force of the desiccant layer to the sealing glass substrate, preventing the desiccant layer from peeling off the sealing substrate.

### BACKGROUND OF THE INVENTION

1. Field of the Invention

The invention relates to a sealing structure of an electroluminescent display device for improving moisture resistance and a method of forming such a sealing structure.

2. Description of the Related Art

In recent years, an organic electroluminescent (hereafter, referred to as EL) display device using an organic EL element, which is a self-emission element, is receiving an attention as a new display device substituting for a CRT or an LCD.

Since the organic EL element is sensitive to moisture, in an organic EL display panel, a structure in which the organic EL element is covered with a metal cap or a glass cap coated with a desiccant has been suggested. FIG. 8 is a cross-sectional view showing such a conventional structure of the organic EL display panel.

A device glass substrate 70 has a display region having many organic EL elements 71 on its surface. The device glass substrate 70 is attached to a sealing glass substrate 80 for sealing the elements with sealing resin 75 made of epoxy resin etc. The sealing glass substrate 80 has a concave portion 81 (hereafter, referred to as a pocket portion 81) in a region corresponding to the above-mentioned display region, which is formed by etching. The pocket portion 81 is coated with a desiccant layer 82 for absorbing moisture on its bottom.

Here, forming of the desiccant layer 82 on the bottom of the pocket portion 81 is for securing a space between the desiccant layer 82 and the organic EL element 71 and accordingly for preventing the desiccant layer 82 from touching the organic EL element 71 and the organic EL element 71 from being damaged. The organic EL display device of this type is described in Japanese Patent Application Publication No. 2001-102166.

### SUMMARY OF THE INVENTION

The invention provides an electroluminescent display device that includes a device glass substrate, an electroluminescent element disposed on a surface of the device glass substrate, and a sealing glass substrate having a surface including a plurality of peak portions and a plurality of valley portions. The sealing glass substrate is attached to the device glass substrate. The device also includes a desiccant layer disposed on the surface of the sealing glass substrate including the peak portions and valley portions. The sealing glass substrate may have a pocket portion on its surface.

The invention also provides a method of manufacturing an electroluminescent display device that includes a device glass substrate provided with an electroluminescent element on a surface thereof, a sealing glass substrate attached to the device glass substrate, and a desiccant layer attached to a surface of the sealing glass substrate. The method includes forming a plurality resist protection layers on the surface of the sealing glass substrate, etching the surface of the sealing glass substrate using the resist protection layers as a mask so as to leave a plurality of protruding portions on the surface of the sealing glass substrate, attaching the desiccant layer to the etched surface of the sealing glass substrate, and attaching the sealing glass substrate to the device glass substrate. Alternatively, the resist pattern may have one opening, and the surface of the sealing glass substrate in the opening may be etched with a hydrofluoric solution containing a substance lowering the solubility of a corrosion product. Furthermore, the surface of the sealing glass may be etched by sandblasting.

### BRIEF DESCRIPTION OF THE DRAWINGS

FIGS. 1A, 1B, 1C, 1D, and 1E are cross-sectional views of device intermediates at manufacturing steps of an electroluminescent display device of a first embodiment of the invention.

FIGS. 2A and 2B are plan views of the device intermediates of the first embodiment of the invention.

FIGS. 3A, 3B, 3C, 3D, and 3E are cross-sectional views of device intermediates at manufacturing steps of an electroluminescent display device of a second embodiment of the invention.

FIGS. 4A, 4B, 4C, and 4D are cross-sectional views of device intermediates at manufacturing steps of an electroluminescent display device of a third embodiment of the invention.

FIGS. 5A, 5B, 5C, 5D, and 5E are cross-sectional views of device intermediates at manufacturing steps of an electroluminescent display device of a fourth embodiment of the invention.

FIG. 6 is a plan view of a pixel of the organic electroluminescent display device of the embodiments.

FIGS. 7A and 7B are cross-sectional views of the pixels of the organic electroluminescent display device of FIG. 6.

FIG. 8 is a cross-sectional view of an electroluminescent display device of a conventional art.

FIG. 9 is a cross-sectional view of the electroluminescent display device of the conventional art after a temperature cycling test.

FIG. 10 is a cross-sectional view of the electroluminescent display device of the conventional art after a temperature cycling test.

### DETAILED DESCRIPTION OF THE INVENTION

It is necessary for the organic EL display panel to secure moisture resistance as well as reliability of device performance against temperature changes. Therefore, a temperature cycling test was conducted in which organic EL panels were subjected to temperature change in a predetermined cycle. It was found that the desiccant layer 82 partially peeled off and came away from the sealing glass substrate 80, as shown in FIG. 9. In addition, the desiccant layer 82 was partially torn off, and the torn-off portion 82A of the desiccant layer 82 moved between the desiccant layer 82 and the device glass substrate 70, as shown in FIG. 10. These defects may result in a damage of the organic EL element 71.

A study into this problem showed that in the course of reducing the panel temperature from a higher temperature, a large contraction occurs in the desiccant layer 82 which has a higher thermal expansion coefficient than the sealing glass substrate 80. On the other hand, since the coefficient of thermal expansion of the sealing glass substrate 80 is lower than that of the desiccant layer 82, the difference generates stresses at the boundary between desiccant layer 82 and the sealing glass 80. When this stress is higher than an adhesive strength of the desiccant layer 82 to the sealing glass substrate 80, the desiccant layer 82 peels off or tears. Therefore, if the adhesive force of the desiccant layer 82 to the sealing glass substrate 80 increases, the desiccant layer 82 can be prevented from peeling off or tearing.

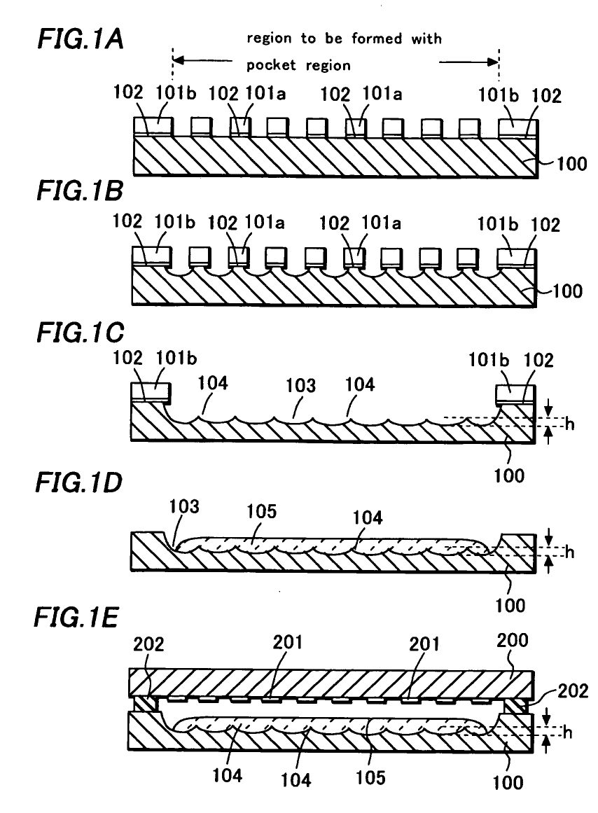

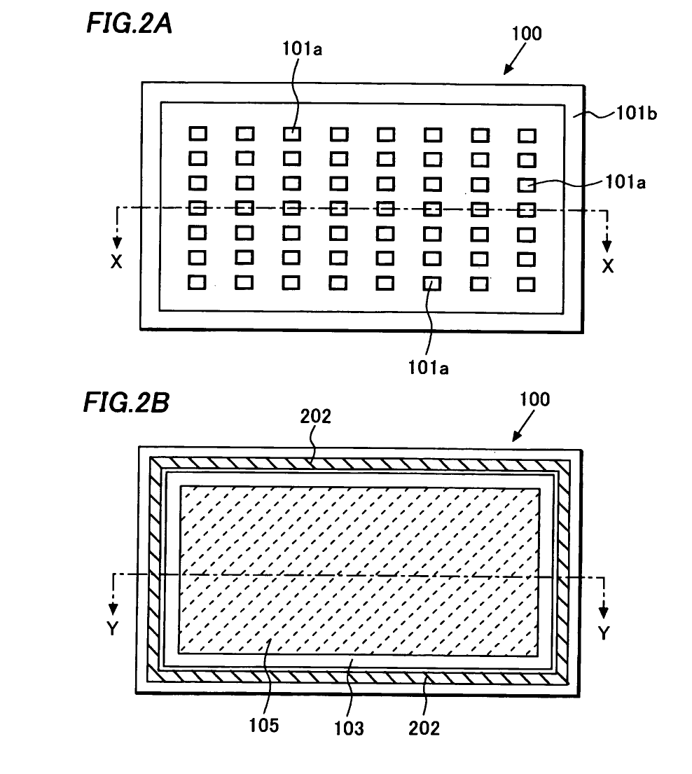

FIGS. 1A, 1B, 1C, 1D, and 1E are cross-sectional views showing manufacturing steps of an electroluminescent display device of a first embodiment of the invention. FIGS. 2A and 2B are plan views of the electroluminescent display device. A cross-section along a line X-X in FIG. 2A corresponds to the cross sectional view of FIG. 1A, and a cross section along a line Y-Y in FIG. 2B corresponds to the cross-sectional view of FIG. 1E.

The manufacturing method of the electroluminescent display device according to the first embodiment will be described hereafter. As shown in FIGS. 1A and 2A, a sealing glass substrate 100 having a thickness of approximately 0.7 mm is prepared. A plurality of resist patterns 101a is formed in a matrix in a region where a pocket portion is to be formed on the sealing glass substrate 100. A resist pattern 101b is formed on a circumference of the region for the pocket portion. It is preferable to form Cr (chromium) mask layers 102 under the resist patterns 101a and 11b. This is for improving etching resistance of a mask when etching the sealing glass substrate 100 as described later. Each width of the plurality of the resist patterns 101a and each interval between the resist patterns 101a are preferably about twice the height of convexes to be formed, for example, 100 micro meters.

Next, as shown in FIG. 1B, a surface of the sealing glass substrate 100 is etched with hydrofluoric acid by using the resist patterns 101a and 101b, and the Cr mask layers 102 as a mask. Since this is wet etching, the etching affects isotropically some regions under the resist patterns 101a and 101b, and the Cr mask layers 102. That is, by this etching, regions between the adjacent resist patterns 101a are formed into shapes like valleys, and regions under the resist patterns 101a are formed into shapes like mountains.

After further etching, the pocket portions 103 are formed as shown in FIG. 1C. The pocket portions 103 are 0.1 mm to 0.3 mm in depth, for example. The resist patterns 101a are removed by peeling when the etching is performed to a predetermined extent. Then, a plurality of concaves and convexes 104 is formed on a bottom of the pocket portion 103 corresponding to the plurality of the resist patterns 101a. Although a height difference h between the concaves and convexes 104 depends on an amount of the resist patterns 101a, the height difference h should be 1 micro meter or more and less than a depth of the pocket portion 103. It is preferably 1 to 300 micro meters, and more preferably 1 to 50 micro meters. These are the height difference appropriate for obtaining an anchor effect which is described later.

Next, as shown in FIG. 1D, the residual resist pattern 101b and the Cr mask layers 102 are removed. Then, a desiccant layer 105 for absorbing moisture is coated on the pocket portion 103. The desiccant layer 105 is attached on the pocket portion 103, for example, by coating a solvent dissolved with powdered calcium oxide or barium oxide and resin as an adhesive on the bottom of the pocket portion 103, and then hardening the solvent by UV irradiation or heating. Since the concaves and convexes 104 are formed on the bottom of the pocket portion 103 (i.e., on the surface of the sealing glass substrate 100) by rough-surface formation as described above, the anchor effect is generated to increase adhesive force of the desiccant layer 105 to the sealing glass substrate 100, preventing the desiccant layer 105 from peeling off the sealing glass substrate 100 and so on.

Then, a device glass substrate 200 is prepared as shown in FIG. 1E. The device glass substrate 200 (a display panel) is approximately 0.7 mm in thickness. The device glass substrate 200 has a display region. The display region includes a plurality of pixels formed in a matrix, and an EL element 201 is disposed in each of the pixels. Detail description of the pixel will be provided below. The device glass substrate 200 is attached to the sealing glass substrate 100 with sealing resin 202 made of epoxy resin etc in a chamber of N₂ gas atmosphere.

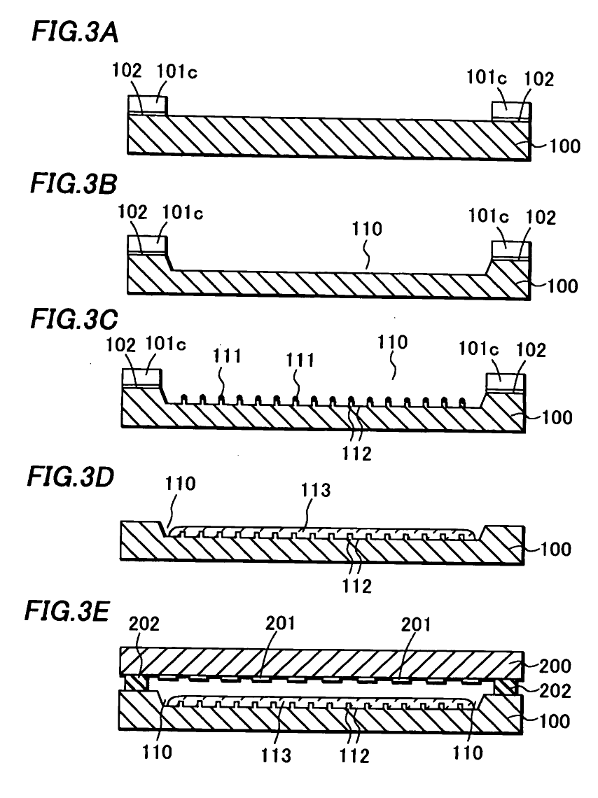

FIGS. 3A, 3B, 3C, 3D and 3E are cross-sectional views showing manufacturing steps of an electroluminescent display device of a second embodiment of the invention. Note that same numerals are used for same portions as those of FIGS. 1A, 1B, 1C, 1D, and 1E.

A sealing glass substrate 100 having a thickness of approximately 0.7 mm is prepared as shown in FIG. 3A. A resist pattern 101c having an opening in a region corresponding to a pocket portion is formed on the sealing glass substrate 100. The resist pattern 101c is formed on a circumference of the region of the pocket portion. It is preferable to form a Cr mask layer 102 under the resist pattern 101c as in the first embodiment. A hydrofluoric acid resistant film can be used for forming the resist pattern 101c, alternatively.

Next, a pocket portion 110 is formed by etching a surface of the sealing glass substrate 100 with hydrofluoric acid by using the resist pattern 101c and the Cr mask layer 102 as a mask, as shown in FIG. 3B. The pocket portion 110 is approximately 0.1 to 0.3 mm in depth. The surface of the pocket portion 110 is further etched with etching liquid made of hydrofluoric acid and a substance (e.g. NH₄F) which highly lowers solubility of corrosion products (e.g. silicofluoride).

Then, as shown in FIG. 3C, corrosion products 111 (e.g. silicofluoride) are attached to a bottom of the pocket portion 110 because solubility of the corrosion products 111 are highly lowered. In regions where the corrosion products 111 are not formed, the sealing glass substrate 100 is etched at a high speed. On the other hand, in regions where the corrosion products 111 are formed, the sealing glass substrate 100 is etched at a lower speed. Accordingly, concaves and convexes 112 are formed on the bottom of the pocket portion 110. A height difference between the concaves and convexes 112 can be controlled by controlling a time for etching with the etching liquid containing the substance which highly lowers the solubility of the corrosion products 111. For obtaining the anchor effect, the height difference should be 1 micro meter or more and less than the depth of the pocket portion 110. Preferably, the height difference is 1 to 300 micro meters, and more preferably 1 to 50 micro meters.

Next, the residual resist pattern 101c and the Cr mask layer 102 are removed as shown in FIG. 3D. A desiccant layer 113 for absorbing moisture is formed on the pocket portion 110. The desiccant layer 113 is attached on the pocket portion 110, for example, by coating a solvent dissolved with powdered calcium oxide or barium oxide and resin as an adhesive on the pocket portion 110, and then hardening the solvent by UV irradiation or heating. Before attaching the desiccant layer 113, the corrosion products 111 may be removed or may not be removed. Since the concaves and convexes 112 are formed on the bottom of the pocket portion 110 (i.e. on the surface of the sealing glass substrate 100) by rough-surface formation as described above, the anchor effect is generated to increase adhesive force of the desiccant layer 113 to the sealing glass substrate 100, preventing the desiccant layer 113 from peeling off the sealing substrate 100 and so on.

Then, the device glass substrate 200 is prepared as shown in FIG. 3E. The device glass substrate 200 is attached to the sealing glass substrate 100 with sealing resin 202 made of epoxy resin etc in a chamber of N₂ gas atmosphere.

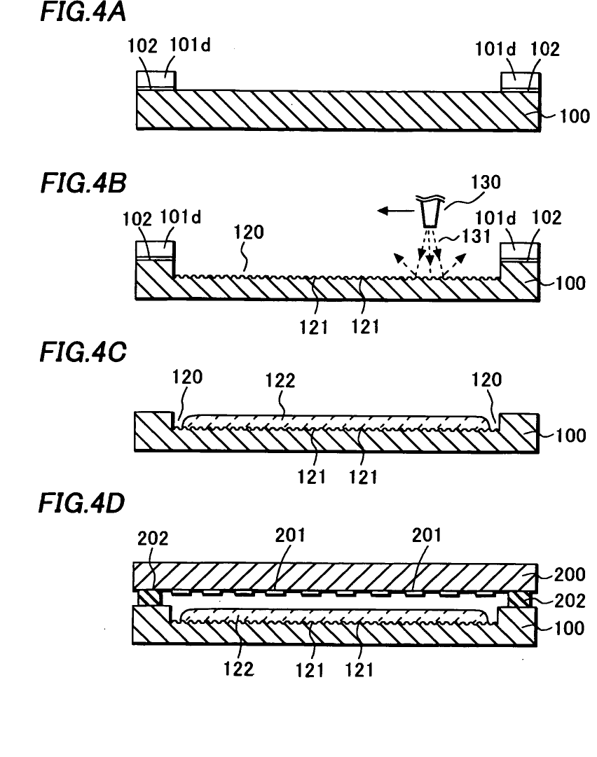

FIGS. 4A, 4B, 4C, and 4D are cross-sectional views showing manufacturing steps of an electroluminescent display device of a third embodiment of the invention in due order. Note that same numerals are used for the same portions as those of FIGS. 1A, 1B, 1C, 1D, and 1E.

As shown in FIGS. 4A, 4B, 4C, and 4D, a sealing glass substrate 100 having a thickness of approximately 0.7 mm is prepared. A resist pattern 101d having an opening in a region for a pocket portion is formed on the sealing glass substrate 100. The resist pattern 101d is formed on a circumference of the region for the pocket portion. A Cr mask layer 102 can be formed under the resist pattern 101d. A hydrofluoric acid resistant film can be used for forming the resist pattern 101d, alternatively.

Next, a pocket portion 120 is formed by etching a surface of the sealing glass substrate 100 by sandblasting as shown in FIG. 4B. By this etching, concaves and convexes 121 are formed at the bottom of the pocket portion 120, i.e., on the surface of the sealing glass substrate 100. The sandblasting is an etching method in which the surface of the sealing glass substrate 100 is etched by applying physical impacts of sands 131 blasted from a blast portion of a micro-nozzle 130 at high pressure while moving the micro-nozzle 130 along the sealing glass substrate 100. If a moving range of the micro-nozzle 130 can be precisely set, masking with the resist pattern 101d and the Cr mask layer 102 is not necessary.

A height difference between the concaves and convexes 121 can be controlled by changing types or particle sizes of sands 131, or sandblasting pressure of the micro-nozzle 130. For obtaining the anchor effect, the height difference is preferably 1 to 300 micro meters, and more preferably 1 to 50 micro meters as described in the first and second embodiments.

Then, a desiccant layer 122 for absorbing moisture is coated on the bottom of the pocket portion 120 (on the etched surface of the sealing glass substrate 100). The desiccant layer 122 is attached to the bottom of the pocket portion 120, for example, by coating a solvent dissolved with powdered calcium oxide or barium oxide and resin as an adhesive on the bottom of the pocket portion 120, and then hardening the solvent by UV irradiation or heating. Since the concaves and convexes 121 are formed on the bottom of the pocket portion 120 by rough-surfacing as described above, the anchor effect is generated to increase adhesive force of the desiccant layer 122 to the sealing glass substrate 100, preventing the desiccant layer 122 from peeling off the sealing substrate 100 and so on.

Then, a device glass substrate 200 is prepared as shown in FIG. 4D. The device glass substrate 200 is attached to the sealing glass substrate 100 with sealing resin 202 made of epoxy resin etc in a chamber of N₂ gas atmosphere.

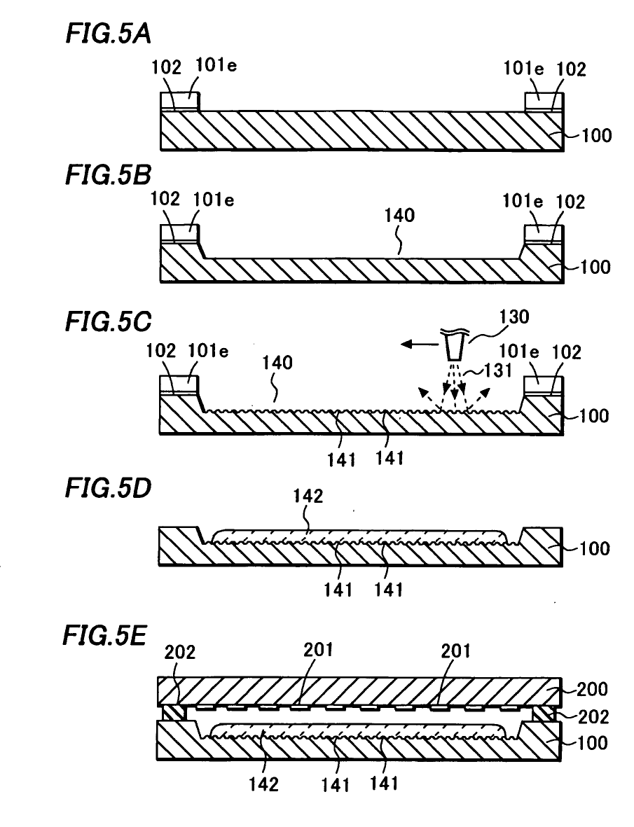

FIGS. 5A, 5B, 5C, 5D, and 5E are cross-sectional views showing manufacturing steps of an electroluminescent display device of a fourth embodiment of the invention. Note that same numerals are used for the same portions as those of FIGS. 1A, 1B, 1C, 1D, and 1E.

As shown in FIG. 5A, a sealing glass substrate 100 having a thickness of approximately 0.7 mm is prepared. A resist pattern 101e having an opening in a region corresponding to a pocket portion is formed on the sealing glass substrate 100. The resist pattern 101e is formed on a circumference of the region for the pocket portion. A Cr mask layer 102 can be formed under the resist pattern 101e.

Next, a pocket portion 140 is formed by etching a surface of the sealing glass substrate 100 with hydrofluoric acid by using the resist pattern 101e and the Cr mask layer 102 as a mask as shown in FIG. 5B. The pocket portion 140 is approximately 0.1 to 0.3 mm in depth.

As shown in FIG. 5C, the surface of the sealing glass substrate 100 is further etched by sandblasting. Then, concaves and convexes 141 are formed on the bottom of the pocket portion 140, i.e. on the surface of the sealing glass substrate 100.

A height difference between the concaves and convexes 141 can be controlled by changing types or particle sizes of sands 131, or sandblasting pressure of the micro-nozzle 130. For obtaining the anchor effect, the height difference is preferably 1 to 300 micro meters, and more preferably 1 to 50 micro meters as described above.

Then, a desiccant layer 142 for absorbing moisture is coated on the bottom of the pocket portion 140, as shown in FIG. 5D. The desiccant layer 142 is attached on the bottom of the pocket portion 140, i.e., on the surface of the sealing glass substrate 100, for example, by coating a solvent dissolved with powdered calcium oxide or barium oxide and resin as an adhesive on the bottom of the pocket portion 140, and then hardening the solvent by UV irradiation or heating. Since the concaves and convexes 141 are formed on the bottom of the pocket portion 140 by rough-surface formation as described above, the anchor effect is generated to increase adhesive force of the desiccant layer 142 to the sealing glass substrate 100, preventing the desiccant layer 142 from peeling off the sealing glass substrate 100 and so on.

Then, a device glass substrate 200 is prepared as shown in FIG. 5E. The device glass substrate 200 is attached to the sealing glass substrate 100 with sealing resin 202 made of epoxy resin etc in a chamber of N₂ gas atmosphere.

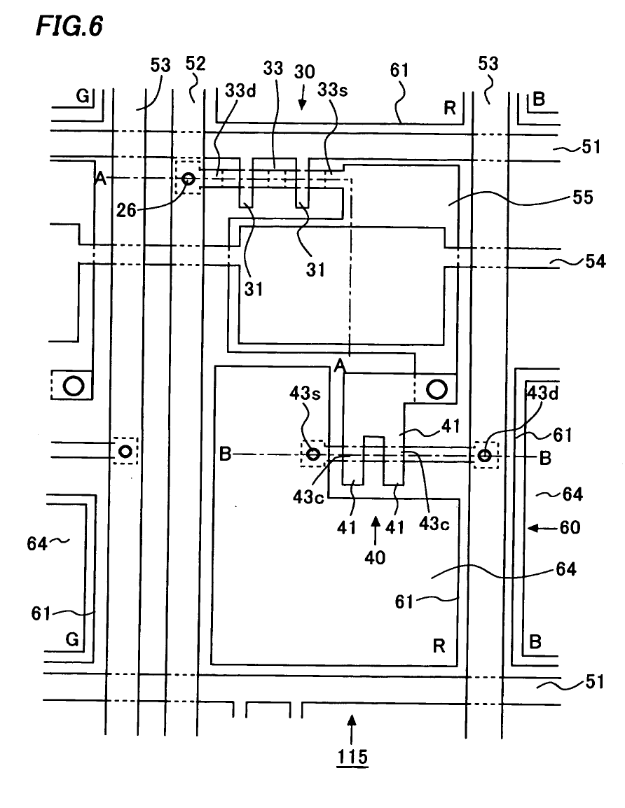

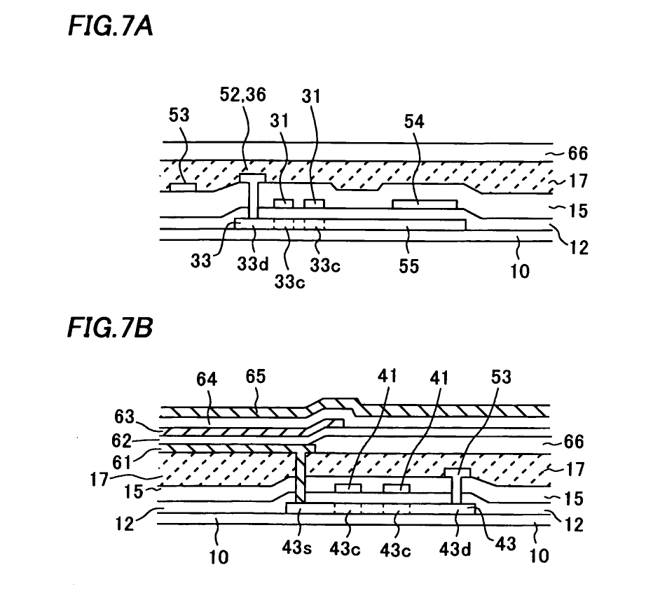

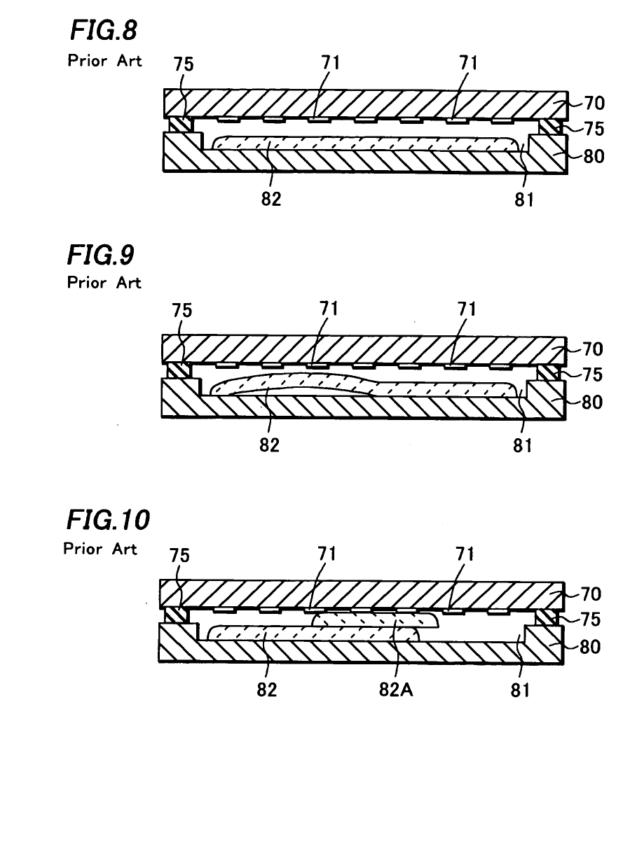

FIG. 6 is a plan view of a pixel of an organic EL display device. FIG. 7A is a cross-sectional view along a line A-A of FIG. 6, and FIG. 7B is a cross-sectional view along a line B-B of FIG. 6.

As shown in FIGS. 6, 7A, and 7B, a pixel 115 is formed in a region enclosed with a gate signal line 51 and a drain signal line 52. A plurality of the pixels 115 is disposed in a matrix.

An organic EL element 60 as a self-emission element, a switching TFT (thin film transistor) 30 for controlling a timing of supplying an electric current to the organic EL element 60, a driving TFT 40 for supplying an electric current to the organic EL element 60, and a storage capacitor are disposed in the pixel 115. The organic EL element 60 is formed of an anode 61, an emissive layer made of an emission material, and a cathode 65.

The switching TFT 30 is provided in a periphery of a point of intersection of the both signal lines 51 and 52. A source 33s of the switching TFT 30 serves as a capacitor electrode 55 for forming a capacitor with a storage capacitor electrode line 54 and is connected to a gate electrode 41 of the driving TFT 40. A source 43s of the driving TFT 40 is connected to the anode 61 of the organic EL element 60, while a drain 43d is connected to a driving source line 53 as a current source to be supplied to the organic EL element 60.

The storage capacitor electrode line 54 is disposed in parallel with the gate signal line 51. The storage capacitor electrode line 54 is made of Cr etc and forms a capacitor by storing an electric charge with the capacitor electrode 55 connected to the source 33s of the TFT 30 through a gate insulating film 12. A storage capacitor 56 is provided for storing voltage applied to the gate electrode 41 of the driving TFT 40.

As shown in FIGS. 7A and 7B, the organic EL display device is formed by laminating the TFTs and the organic EL element sequentially on a substrate 10 such as a substrate made of glass or synthetic resin, a substrate having conductivity, or a semiconductor substrate. When using a substrate having conductivity or a semiconductor substrate as the substrate 10, however, an insulating film such as SiO₂ or SiNₓ is formed on the substrate 10, and then the switching TFT 30, the driving TFT 40 and the organic EL element 60 are formed thereon. Each of the TFTs has a so-called top gate structure in which a gate electrode is disposed above an active layer with a gate insulating film being interposed therebetween.

The switching TFT 30 will be described first. As shown in FIG. 7A, an amorphous silicon film (hereafter, referred to as an a-Si film) is formed on the insulating substrate 10 made of silica glass, non-alkali glass, etc by a CVD method etc. The a-Si film is irradiated with laser beams for melting and recrystalizing to form a poly-silicon film (hereafter, referred to as a p-Si film) as an active layer 33. On the active layer 33, a single-layer or a multi-layer of an SiO₂ film and an SiNₓ film is formed as the gate insulating film 12. The gate signal line 51 made of metal having a high melting point such as Cr or Mo (molybdenum) and serving as a gate electrode 31, the drain signal line 52 made of Al (aluminum), and the driving source line 53 made of Al and serving as a driving source of the organic EL element are provided on the gate insulating film 12.

An interlayer insulating film 15 laminated with an SiO₂ film, an SiNₓ film and an SiO₂ film sequentially is formed on whole surfaces of the gate insulating film 12 and the active layer 33. There is provided a drain electrode 36 by filling a contact hole provided for corresponding drain 33d with metal such as Al. Furthermore, a planarization insulating film 17 for planarizing a surface which is made of organic resin is formed on the whole surface.

Next, the driving TFT 40 of the organic EL element will be described. As shown in FIG. 7B, an active layer 43 formed by poly-crystalizing an a-Si film by irradiating the film with laser beams, the gate insulating film 12, and the gate electrode 41 made of metal having a high melting point such as Cr or Mo are formed sequentially on the insulating substrate 10 made of silica glass, non-alkali glass, etc. A channel 43c, and a source 43s and a drain 43d on both sides of the channel 43c are provided in the active layer 43. The interlayer insulating film 15 laminated with an SiO₂ film, an SiNₓ film and an SiO₂ film sequentially is formed on the whole surfaces of the gate insulating film 12 and the active layer 43. The driving source line 53 is connected to a driving source by filling a contact hole provided for corresponding drain 43d with metal such as Al. Furthermore, a planarization insulating film 17 for planarizing a surface, which is made of, for example, organic resin etc is formed on the whole surface. A contact hole is formed in a position corresponding to a source 43s in the planarization insulating film 17. A transparent electrode made of ITO (Indium Tin Oxide) and contacting the source 43s through the contact hole, i.e., the anode 61 of the organic EL element, is formed on the planarization insulating film 17. The anode 61 is formed in each of the pixels, being isolated as an island.

The organic EL element 60 has a structure of laminating sequentially the anode 61 made of a transparent electrode such as ITO, a hole transport layer 62 made of a first hole transport layer made of MTDATA (4,4-bis(3-methylphenylphenylamino) biphenyl) and a second hole transport layer made of TPD (4,4,4-tris(3-methylphenylphenylamino)triphenylanine), an emissive layer 63 made of Bebq2 (bis(10-hydroxybenzo[h]quinolinato)beryllium) containing a quinacridone derivative, an electron transport layer 64 made of Bebq2, and a cathode 65 made of magnesium-indium alloy, Al or Al alloy.

The planarization insulating film 17 is formed with a second planarization insulating film 66 thereon. The second planarization insulating film 66 is removed on the anode 61.

In the organic EL element 60, a hole injected from the anode 61 and an electron injected from the cathode 65 are recombined in the emissive layer 63 and an exciton is formed by exciting an organic module forming the emissive layer 63. Light is emitted from the emissive layer 63 in a process of radiation of the exciton and then released outside after going through the transparent anode 61 to the transparent insulating substrate 10, thereby to complete a light-emission.

What is claimed is:

1. An electroluminescent display device comprising:
a device glass substrate;
an electroluminescent element disposed on a surface of the device glass substrate;
a sealing glass substrate having a surface comprising a plurality of peak portions and a plurality of valley portions, the sealing glass substrate being attached to the device glass substrate; and
a desiccant layer disposed on the surface of the sealing glass substrate comprising the peak portions and valley portions.

2. The electroluminescent display device of claim 1, wherein a height difference between the peak portions and the valley portions is 1 to 300 micro meters.

3. An electroluminescent display device comprising:
a device glass substrate;
an electroluminescent element disposed on a surface of the device glass substrate;
a sealing glass substrate attached to the device glass substrate;
a recess formed on a surface of the sealing glass substrate and having a surface comprising a plurality of peak portions and a plurality of valley portions; and
a desiccant layer disposed on the surface of the recess comprising the peak portions and the valley portions.

4. The electroluminescent display device of claim 2, wherein a height difference between the peak portions and the valley portions is 1 to 300 micro meters.

5. A method of manufacturing an electroluminescent display device comprising a device glass substrate provided with an electroluminescent element on a surface thereof, a sealing glass substrate attached to the device glass substrate, and a desiccant layer attached to a surface of the sealing glass substrate, the method comprising:
forming a plurality resist protection layers on the surface of the sealing glass substrate;
etching the surface of the sealing glass substrate using the resist protection layers as a mask so as to leave a plurality of protruding portions on the surface of the sealing glass substrate;
attaching the desiccant layer to the etched surface of the sealing glass substrate; and
attaching the sealing glass substrate to the device glass substrate.

6. The method of manufacturing an electroluminescent display device of claim 5, wherein the sealing glass substrate is attached to the device glass substrate using a sealing resin.

7. A method of manufacturing an electroluminescent display device comprising a device glass substrate provided with an electroluminescent element on a surface thereof, a sealing glass substrate attached to the device glass substrate, and a desiccant layer attached to a surface of the sealing glass substrate, the method comprising:
forming a resist pattern having an opening on the surface of the sealing glass substrate;
etching the surface of the sealing glass substrate with a first hydrofluoric acid solution using the resist pattern as an etching mask;
further etching the etched surface of the sealing glass substrate with a second hydrofluoric acid solution containing a substance lowering a solubility of a corrosion product using the resist pattern as the etching mask;
attaching the desiccant layer to the surface of the sealing glass substrate etched with the first and second hydrofluoric acid solutions; and
attaching the sealing glass substrate to the device glass substrate.

8. The method of manufacturing an electroluminescent display device of claim 7, wherein the sealing glass substrate is attached to the device glass substrate using a sealing resin.

9. A method of manufacturing an electroluminescent display device comprising a device glass substrate provided with an electroluminescent element on a surface thereof, a sealing glass substrate attached to the device glass substrate, and a desiccant layer attached to a surface of the sealing glass substrate, the method comprising:
forming a resist pattern having an opening on the surface of the sealing glass substrate;
sandblasting the surface of the sealing glass substrate using the resist pattern as a mask;
attaching the desiccant layer to the sandblasted surface of the sealing glass substrate; and
attaching the sealing glass substrate to the device glass substrate.

10. The method of manufacturing an electroluminescent display device of claim 9, wherein the sealing glass substrate is attached to the device glass substrate using a sealing resin.

11. A method of manufacturing an electroluminescent display device comprising a device glass substrate provided with an electroluminescent element on a surface thereof, a sealing glass substrate attached to the device glass substrate, and a desiccant layer attached to a surface of the sealing glass substrate, the method comprising:
forming a resist pattern having an opening on the surface of the sealing glass substrate;
etching the surface of the sealing glass substrate using the resist pattern as a mask;
sandblasting the etched surface of the sealing glass substrate;
attaching the desiccant layer to the sandblasted surface of the sealing glass substrate; and
attaching the sealing glass substrate to the device glass substrate.

12. The method of manufacturing an electroluminescent display device of claim 11, wherein the sealing glass substrate is attached to the device glass substrate using a sealing resin.

13. An electroluminescent display device comprising:
a device glass substrate;
an electroluminescent element disposed on a surface of the device glass substrate;
a sealing glass substrate attached to the device glass substrate;
a desiccant layer attached to the sealing glass substrate so that the desiccant layer is disposed between the device glass substrate and the sealing glass substrate; and
means for forming physical anchoring between the desiccant layer and the sealing glass substrate.
